(19) United States
(12) Patent Application Publication
(10) Pub. No.: US 2003/0151418 A1
(43) Pub. Date: Aug. 14, 2003

(54) Low voltage circuit tester

(76) Inventor: Roger Joseph Leger, Powell River (CA)

Correspondence Address: OYEN, WIGGS, GREEN & MUTALA, 480 - THE STATION, 601 WEST CORDOVA STREET, VANCOUVER, BC, V6B 1G1, CA

(21) Appl. No.: 10/067,960

(22) Filed: Feb. 8, 2002

(51) Int. Cl. G01R 27/08

(52) U.S. Cl. 324/715

(57) ABSTRACT

A circuit tester comprises a reference voltage source, an indicator with first and second response states, an indicator driver connected to the reference voltage source, an oscillator and a probe. The oscillator's output and the probe are both connected to the indicator driver's input. The indicator driver drives the indicator in the first response state when the voltage at the input is lower than the reference voltage, and in the second response state when the voltage at the input is higher than the reference voltage. The oscillator causes the indicator driver to cycle the indicator between the first and second response states when the probe is not connected to a circuit under test.

### TECHNICAL FIELD

The invention relates generally to circuit testing and, particularly, to testing voltage levels of electrical circuits at various points. The invention has particular application to testing electrical control systems in automobiles.

### BACKGROUND

Automobiles and other modern consumer products typically include electrical circuits which can malfunction. Malfunctions may occur, for example, when components fail, electrical connections become unreliable or degrade, short circuits occur or open circuits occur. There is a need for diagnostic tools which are useful for diagnosing faults such as those noted above. There is a particular need for such tools which are affordable.

To diagnose faults in an electrical circuit it is often necessary to test the voltage level of the circuit at various points. There are various prior art devices that can be used to probe voltage levels of an electrical circuit. For example, U.S. Pat. No. 5,270,638 discloses a probe device that has two light emitting diodes (LEDs), one LED indicates the polarity and quality of a connection to a power source, and one LED indicates a polarity of the voltage tested by the probe.

U.S. Pat. No. 5,572,143 discloses a circuit testing device having a probe and three LEDs. The first LED is used to indicate that the device is properly connected to the power source and that there is no voltage or signal detected at the probe, the second to indicate when the voltage at the probe changes, and the third to indicate that a steady voltage level is detected at the probe.

U.S. Pat. No. 5,672,964 discloses a voltage probe testing device with either one two-color LED or two separate LEDs for indicating the voltage present at the probe and a lamp or bulb to illuminate the test area, all contained within an ergonomic housing.

U.S. Pat. No. 5,789,911 discloses a polarity testing probe that has two LEDs connected to the probe so that one lights up when a first polarity is detected, and the other lights up when a second polarity is detected.

The inventor has noticed that none of the devices disclosed in the above patents provide a single indicator that can be used to indicate that voltage at the testing location is high, low or that there is no voltage present at the testing location, and at the same time whether or not a good connection with the power source has been established.

Logic probes are available for testing logic-level signals in digital circuits. Such logic probes are typically limited to testing voltage levels in the range of 0 to 5 volts and are unsuited to testing circuits of the type found in automobiles, boats, airplanes or the like.

There exists a need for a reliable and inexpensive circuit tester that can be used to quickly and easily probe the voltage levels of an electrical circuit at varying locations. There further exists a need for a circuit tester that will indicate the polarity of a point on a circuit under test accurately, regardless of how the circuit tester is connected to its power source.

### SUMMARY OF THE INVENTION

One aspect of the invention provides a circuit tester which comprises a reference voltage source, an indicator with first and second response states, an indicator driver connected to the reference voltage having an input and connected to drive the indicator, an oscillator with an output connected to the indicator driver's input, and a probe which is also connected to the indicator driver's input. The indicator driver drives the indicator in the first response state when the voltage at the input is lower than the reference voltage, thereby producing a first indication, and in the second response state when the voltage at the input is higher than the reference voltage, thereby producing a second indication. The oscillator causes the indicator driver to cycle the indicator between the first and second response states when the probe is not connected to a circuit under test, or is connected to a point on the circuit under test that has a voltage approximately equal to the reference voltage, thereby producing a third indication.

The indicator may comprise a two-color light emitting diode (LED) that emits light of a first color and a second color, with the first and second response states comprising displaying the first and second colors, respectively.

Alternatively, the indicator may comprise an audio signal generator that emits sound of a first pitch and a second pitch, with the first and second response states comprising emitting sound of the first and second pitches, respectively.

The oscillator may generate a signal that oscillates so quickly that the indicator provides a third indication, the third indication being a mixture of the first and second response states, when the probe is not connected to a circuit under test, or is connected to a point on the circuit under test that has a voltage approximately equal to the reference voltage. In embodiments where the indicator comprises a two-color LED, the third indication may appear to be a third color which is a blend of the first and second colors. In embodiments where the indicator comprises an audio signal generator, the third indication may comprise sound having a third pitch which is a mixture of the first and second pitches.

The indicator driver may comprise first and second comparators each having an output, a non-inverting input and an inverting input with the indicator connected between the outputs of the first and second comparators. The reference voltage source is coupled to the non-inverting input of the first comparator and the inverting input of the second comparator. The inverting input of the first comparator is connected to the non-inverting input of the second comparator and the input of the indicator driver is resistively coupled to the inverting input of the first comparator and the non-inverting input of the second comparator.

The oscillator may comprise a relaxation oscillator. The relaxation oscillator may comprise a comparator having first and second inputs and an output, with the reference voltage source connected to the first input, a resistor connected between the output and the first input, a capacitor connected to the second input, and a resistor connected between the output and the second input. The reference voltage source may comprise a voltage divider, a voltage regulator, or the like.

The circuit tester may comprise first and second power connectors respectively connected to first and second inputs of a full-wave rectifier having positive and negative outputs. The reference voltage source may comprise a voltage divider connected between the positive and negative outputs of the full-wave rectifier. The first and second power connectors may be connected to a power source. The power source may be a battery with a voltage between about 6 and 24 volts. The indicator driver may comprise a current limiter, so that the operation of the circuit tester is substantially unaffected by variations in the voltage of the power source. The current limiter may comprise, for example, the output stage of an integrated circuit such as an LM324 operational amplifier.

In embodiments where the first and second power connectors are connected to a power source, the first and second response states of the indicator may operate at a full intensity level when the power connectors have made a good connection with the power source, and a lower intensity level when the power connectors have not made a good connection with the power source.

In embodiments where the reference voltage source comprises a voltage divider, the voltage divider may comprise two equivalent resistors so that the reference voltage is halfway between the voltage levels on the conductors between which the voltage divider is connected.

The circuit tester may comprise a current steering resistor connected in series with the probe. The current steering resistor preferably has a value such that when both of the first and second power connectors are connected to a power source, such as a 12 volt battery, the current passing through the probe does not exceed approximately 1 milliampere under expected operating conditions.

In another aspect of the invention, the circuit tester includes a power connector connected to a first input of a full-wave rectifier having positive and negative outputs. In this aspect the probe is connected to a second input of the full-wave rectifier, and the reference voltage source comprises a voltage divider connected between the high and low outputs of the full-wave rectifier.

A further aspect of the invention provides a circuit tester comprising: first, second and third connectors; first, second, third, fourth, fifth and sixth diodes, each diode having an anode and a cathode, the anodes of said first, third and fifth diodes connected to said first, second and third connectors, respectively, and the cathodes of said second, fourth and sixth diodes connected to said first, second and third connectors, respectively; and, a testing circuit having a positive input, a negative input, and a probe input; wherein the cathodes of said first, third and fifth diodes are connected to the positive input of said testing circuit, and the anodes of said second, fourth and sixth diodes connected to the negative input of said testing circuit, and one of said connectors is connected to the probe input of said testing circuit.

Another aspect of the invention provides a method for testing a circuit. The method comprises: producing a reference voltage; providing a tester circuit comprising an indicator, an oscillator and a probe, the indicator having first and second response states; connecting the probe to a test point on a circuit under test; and, producing an indication from the indicator, wherein when a voltage at the test point is lower than the reference voltage the indication comprises the first response state, and when a voltage at the test point is higher than the reference voltage the indication comprises the second response state, and when a voltage at the test point is floating the oscillator causes the indication to cycle between the first and second response states.

Further features and advantages of the invention are described below.

### BRIEF DESCRIPTION OF THE DRAWINGS

In drawings which illustrate non-limiting embodiments of the invention:

FIG. 1 is a schematic block diagram of a circuit tester constructed according to the invention;

FIG. 2 is a detailed circuit diagram of a first embodiment of the circuit tester;

FIG. 3 is a circuit diagram of a malfunctioning circuit; and,

FIG. 4 is a circuit diagram of a circuit in which faults can be detected using the circuit tester of FIG. 2.

### DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive, sense.

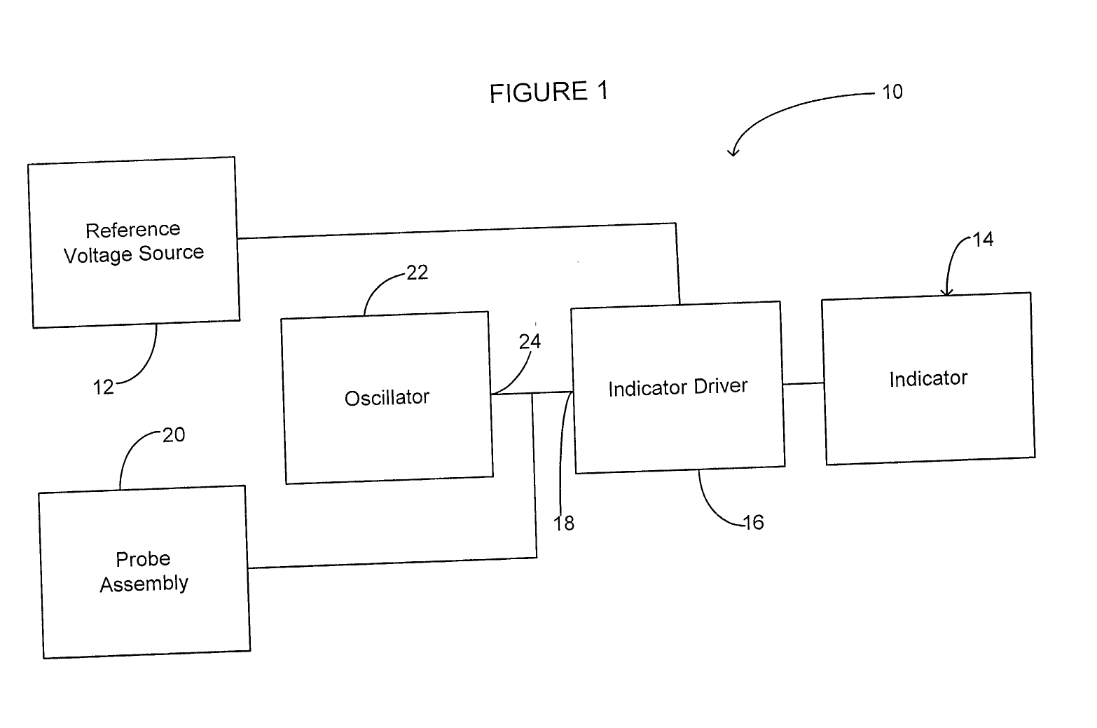

The invention is directed to a circuit tester. Circuit tester may be used to determine whether an adequate voltage level at a given point on a circuit under test is present. FIG. 1 is a block diagram which shows the basic elements of a circuit tester 10 according to a preferred embodiment of the invention.

A reference voltage source 12 supplies a reference voltage to which the voltage level at a test point in a circuit under test may be compared. In auto mechanics a car's electrical system is generally powered by a battery having a negative terminal which is grounded to the frame of the car. Throughout the description, except where otherwise noted, voltages higher than the reference voltage are referred to as “high”, and voltages lower than the reference voltage are referred to as “low”.

In typical automotive applications involving a standard “12 volt” negative ground electrical system, the reference voltage may be about 6 volts in which case the “high” voltages will be in the range of about 6 to 13 volts (a lead-acid battery which is nominally 12 volts has an open-circuit voltage when fully charged of 13 volts) and the “low” voltage will be in the range of about 0 to 6 volts. The reference voltage is preferably in the range of about ¼ to ¾ of the maximum voltage expected in the circuit under test (i.e. in the range of about 3 to 9 volts in the standard “12 volt” automotive electrical system). Tester 10 determines whether the voltage at the point of the circuit being tested is above the reference voltage (high or “positive polarity”) or below the reference voltage (low or “negative polarity”). In the embodiments of the invention wherein the reference voltage source 12 comprises a voltage divider, the reference voltage will be a fraction (for example one half) of the voltage of the power source.

Tester 10 is preferably configured for use with a power source such as a battery with a voltage of between about 6 and 24 volts. Preferably, the operation of tester 10 is substantially unaffected by the voltage of the power source.

Tester 10 has an indicator 14 which has first and second response states. Indicator 14 indicates the voltage level or polarity at the current test point in the circuit under test. The operation of indicator 14 is controlled by an indicator driver 16.

Indicator driver 16 has an input 18. Indicator driver 16 causes indicator 14 to operate in the first response state and produce a first indication when the voltage level at input 18 is low, and to operate in the second response state and produce a second indication when the voltage level at input 18 is high.

Input 18 of indicator driver 16 is connected to a probe assembly 20 and an output 24 of an oscillator 22. Probe assembly 20 is electrically connected to input 18, so that if probe assembly 20 is in electrical contact with a test point in the circuit under test that has a voltage lower than the reference voltage, then input 18 will be presented with a voltage lower than the reference voltage. Likewise, if probe assembly 20 is connected to a test point in the circuit under test that has a voltage higher than the reference voltage, then input 18 will be presented with a voltage higher than the reference voltage.

Oscillator 22 provides an oscillating signal to input 18 so that, when probe assembly 20 is not connected to a circuit under test, or probe assembly 20 is connected to a point on the circuit under test that has a voltage level approximately equal to the reference voltage, or the portion of the circuit under test to which probe assembly 20 is connected is “floating” then input 18 cycles between a positive and a negative voltage. This in turn causes indicator 14 to cycle between its first and second response states. Oscillator 22 preferably provides a signal with a frequency high enough so that when indicator 14 cycles between its first and second response states, at a frequency determined by oscillator 22, indicator 14 seems to produce a third indication.

Indicator 14 preferably comprises a two-color LED. In this embodiment, indicator 14 displays a first color as the first indication and a second color as the second indication. When indicator 14 is quickly cycling between the first and second response states, the two-color LED appears to produce a third indication. In this example, the third indication is a third color which is a blend of the first and second colors. For example, if the first color is green and the second color is red then the LED may appear yellow when it is cycling rapidly between red and green. For example, oscillator 22 could cause the LED to cycle at a frequency in excess of about 10 Hz and preferably in excess of about 30 Hz.

In another embodiment of the invention, indicator 14 may comprise two separate display elements which may comprise LEDs, LCDs, lamps or the like, rather than a two-color LED. In this embodiment, one display element is activated as the first indication, the other display element is activated as the second indication and both display elements are activated in alternation as the third indication.

In yet another embodiment of the invention indicator 14 may comprise three distinct display elements driven by a circuit which causes a first one of the display elements to be activated when the voltage of the test point is high, a second one of the display elements to be activated when the voltage of the test point is low, and a third one of the display elements to be activated when the voltage of the test point is approximately equal to the reference voltage.

In still another embodiment of the invention indicator 14 may comprise an audio signal generator. In this embodiment, indicator 14 can emit a first pitch as the first indication and a second pitch as the second indication. When indicator 14 is cycling between its first and second response states, the audio signal generator can produce a third indication which is a sound comprising a mixture of the first and second pitches.

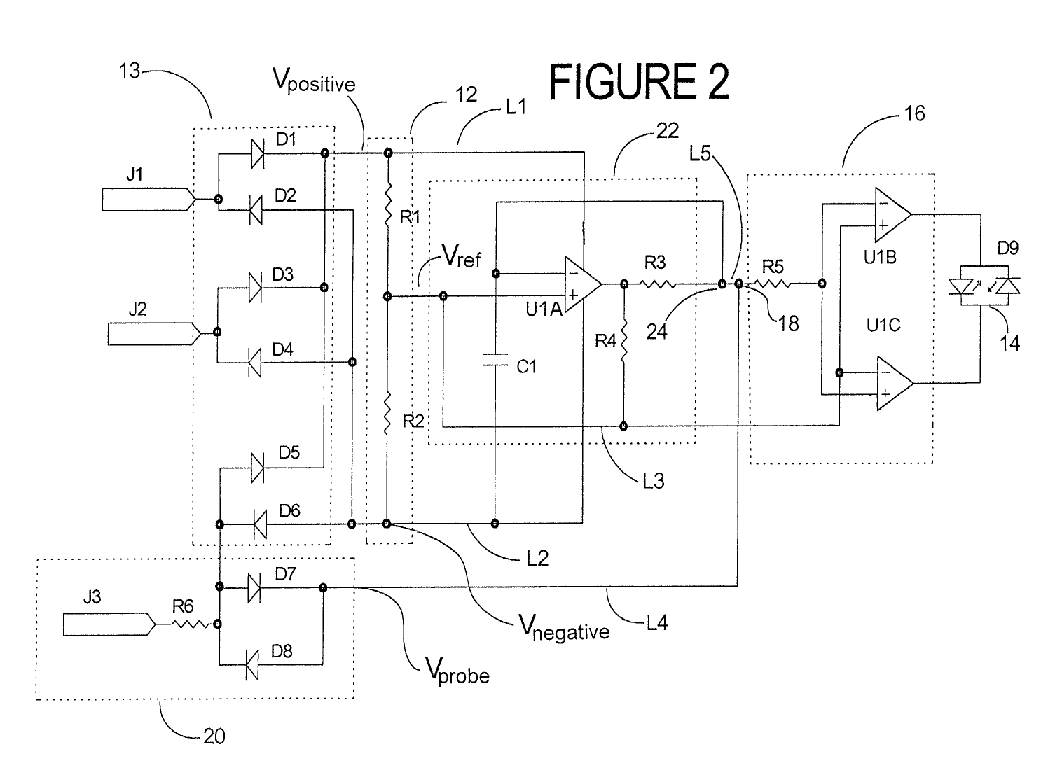

FIG. 2 is a detailed circuit diagram of a circuit tester 10 constructed according to a currently preferred embodiment of the invention.

In this embodiment, reference voltage source 12 provides a reference voltage V_{ref}. Reference voltage source 12 comprises a voltage divider formed by resistors R1 and R2 connected in series between a positive line L1 and a negative line L2. The output of the voltage divider is connected to a reference line L3. Resistors R1 and R2 can be chosen to be equivalent, so that the reference voltage V_{ref}, which is provided to reference line L3, is halfway between positive voltage Vₚₒₛᵢₜᵢᵥₑ and negative voltage V_{negative} (assuming a negligible current draw on reference line L3).

Circuit tester 10 preferably comprises a full wave rectifier 13. Rectifier 13 comprises a first pair of diodes D1, D2, a second pair of diodes D3, D4, and a third pair of diodes D5, D6. A first output of rectifier 13, at the cathodes of diodes D1, D3 and D5, provides a positive voltage Vₚₒₛᵢₜᵢᵥₑ to line L1. A second output of rectifier 13, at the anodes of diodes D2, D4 and D6, provides a negative voltage V_{negative} to line L2. First and second power connectors J1 and J2 are connected to first and second diode pairs D1, D2 and D3, D4, respectively. Probe J3 is connected to third diode pair D5, D6 through a current limiting resistor R6. In normal operation, J1 and J2 are each connected to one terminal of a DC power supply, such as a battery (not shown). This provides a positive voltage to L1 and a negative voltage to L2, regardless of the polarity of J1 and J2. In an alternative mode of operation, if only one of J1, J2 are connected to a power supply, or both J1 and J2 are connected to the same terminal of a power supply, power is supplied to lines L1, L2 from the circuit under test through J3, R6 and diode pair D5, D6, as described below.

In the embodiment of FIG. 2, indicator driver 16 comprises two comparators U1B and U1C and a resistor R5. Each comparator U1B and U1C has a non-inverting input (+), an inverting input (−), and an output. Non-inverting input (+) of comparator U1B is connected to inverting input (−) of comparator U1C, and inverting input (−) of comparator U1B is connected to non-inverting input (+) of comparator U1C in push-pull fashion, so that comparators U1B and U1C are 180 degrees out of phase with each other (i.e. the output of comparator U1B is positive while that of comparator U1C is negative and vice versa).

Input 18 of indicator driver 16 is connected through resistor R5 to inverting input (−) of comparator U1B and non-inverting input (+) of comparator U1C. Reference line L3 is connected to non-inverting input (+) of comparator U1B and inverting input (−) of comparator U1C to provide indicator driver 16 with reference voltage V_{ref}.

Indicator 14 preferably comprises a single two-color LED D9 connected between the outputs of comparator U1B and comparator U1C. LED D9 may include a suitable current-limiting resistor. LED D9 produces a first indication comprising light of a first color, preferably green, in a first response state when current is flowing from the output of comparator U1B to the output of comparator U1C (i.e. the output of comparator U1B is positive and the output of comparator U1C is negative). LED D9 produces a second indication comprising light of a second color, preferably red, in a second response state when current is flowing from the output of comparator U1C to the output of comparator U1B (i.e. the output of comparator U1C is positive and the output of comparator U1B is negative).

Input 18 is connected to probe assembly 20 by means of line L4. Probe assembly 20 provides a probe voltage V_{probe} to line L4. If V_{probe} is lower than V_{ref} (V_{probe} is low), the output of comparator U1B will be positive and the output of comparator U1C will be negative, and indicator 14 will produce the first indication by displaying light of the first color, preferably green. If V_{probe} is higher than V_{ref} (V_{probe} is high), the output of comparator U1B will be negative and the output of comparator U1C will be positive, and indicator 14 will produce the second indication by displaying light of the second color, preferably red.

In the embodiment of FIG. 2, probe assembly 20 comprises probe J3, resistor R6, and a pair of opposed diodes D7 and D8. R6 may be called a “current steering” resistor. The cathode of diode D7 and the anode of diode D8 are connected to line L4. The anode of diode D7 and the cathode of diode D8 are both connected to one end of resistor R6. The other end of resistor R6 is connected to probe J3, which the user places in electrical connection with a test point in the circuit under test in order to pass the voltage of the test point Vₜₑₛₜ on to line L4 as probe voltage V_{probe}. (Note that V_{probe} will be slightly lower than Vₜₑₛₜ due to the voltage drop across resistor R6 and diodes D7 and D8). This configuration of probe assembly 20 serves to reduce the current which passes through probe J3 so that delicate components of the circuit under test will not be damaged and so that the circuit under test does not get loaded down by probe J3. The value of R6 may be chosen so that the impedance between J3 and each of L1 and L2 is significantly greater than the impedance between each of J1 and J2 and each of L1 and L2. R6 may, for example, have an impedance of a few hundred ohms. Preferably, in normal operation wherein J1 and J2 are connected across a DC power supply, the current passing through probe J3 will not exceed 1 milliampere.

The embodiment of FIG. 2 also provides for probe J3 to take the place of one of the power connectors J1 or J2, to supply power to L1 and L2 from the circuit under test. If, for example, connector J1 is connected to a positive lead of a DC power source, connector J2 is not connected to anything, and probe J3 is connected to a test voltage in the circuit under test that is near ground potential, positive line L1 is provided with positive voltage Vₚₒₛ, from the positive lead of the DC power source, and negative line L2 is provided with negative voltage V_{negative} from the circuit under test through probe assembly 20. Likewise, if connector J1 is connected to a ground lead of a DC power source, connector J2 is not connected to anything, and probe J3 is connected to a test voltage in the circuit under test that is a positive voltage, positive line L1 is provided with positive voltage Vₚₒₛᵢₜᵢᵥₑ from the circuit under test through probe assembly 20, and negative line L2 is provided with negative voltage V_{negative} from the ground lead of the DC power source. The above functioning remains unchanged if it is connector J2 that is connected to a DC power source and connector J1 that is not connected to anything, or if both J1 and J2 are connected to the same lead of a power source, since connectors J1 and J2 are equivalent. Note, however, that in this mode of operation higher currents may pass through probe J3.

Input 18 of indicator driver 16 is connected to output 24 of oscillator 22 by means of line L5. As described above, oscillator 22 provides an oscillating signal to input 18 so that, when probe assembly 20 is not connected to a circuit under test, or probe assembly 20 is connected to a point of the circuit under test that has a voltage level approximately equal to reference voltage V_{ref}, input 18 cycles between a positive and a negative voltage. This in turn causes indicator 14 to cycle between first and second response states. Oscillator 22 preferably provides a signal with a frequency high enough so that when indicator 14 cycles between first and second response states, indicator 14 produces a third indication, where the LED is alternating between emitting green light and red light so fast that it appears to be emitting yellow light.

In the embodiment of FIG. 2, oscillator 22 comprises a comparator U1A, resistors R3 and R4, and a capacitor C1. Comparator U1A has a non-inverting input (+), an inverting input (−), and an output. Inverting input (−) of comparator U1A is connected to negative line L2 through capacitor C1, to output 24, and to one end of resistor R3. The other end of resistor R3 is connected to the output of comparator U1A. Non-inverting input (+) of comparator U1A is connected to reference line L3, and to one end of resistor R4. The other end of resistor R4 is connected to the output of comparator U1A. Capacitor C1 and resistors R3 and R4 are preferably chosen so that oscillator 22 produces a signal with a frequency of approximately 2 kHz at output 24.

In order to minimize the complexity and cost of circuit tester 10, comparators U1A, U1B and U1C are all preferably located on a single IC chip. The IC chip may be supplied with electrical power from positive line L1 and negative line L2. The IC chip preferably comprises a chip that includes a current limiter, such as a LM324 chip which has a short circuit protection feature that limits the output current of the chip to approximately 25 milliamperes. For this reason the embodiment of FIG. 2 does not require a separate current limiting resistor in series with LED D9.

In operation, a user can connect probe J3 to a point on a circuit that the user is testing. The user will be able to determine if the circuit is malfunctioning if, for example, a point on the circuit is supposed to be grounded but, when probe J3 is connected to that point, LED D9 is not green.

Further, the user may be able to diagnose the type of problem with the circuit. If the user expects a point on the circuit to be grounded, but LED D9 turns red (indicating a high voltage) when probe J3 is connected to that point, the user should look for a short connecting that point on the circuit to the positive terminal of the DC power source. On the other hand, if LED D9 appears yellow when probe J3 is connected to that point, this may indicate the connection between that point and the ground line is faulty.

As an example, consider the case where an electrical component in an automobile is not working. The user may determine, after consulting a manual, that a certain test on the circuit for that component should have a voltage level of 12V. If a standard 12V car battery is used for the power source for tester 10, the reference voltage may be 6V. Thus, the user would know that if probe J3 is connected to a point on the circuit where the voltage level is 12V, LED D9 will be green. If the user connects probe J3 to the test point on the circuit for the malfunctioning component that should have a voltage level of 12V and LED D9 turns green, the user can look elsewhere for the cause of the malfunction. If, however, LED D9 remains yellow or turns red, the user can then follow the circuit back to the positive terminal of the battery by probing successive points along the circuit. When the user probes a point that causes LED D9 to turn green, the user knows that the problem with the circuit is between that point and the previously probed point The user can then examine that portion of the circuit for loose connections or short circuits.

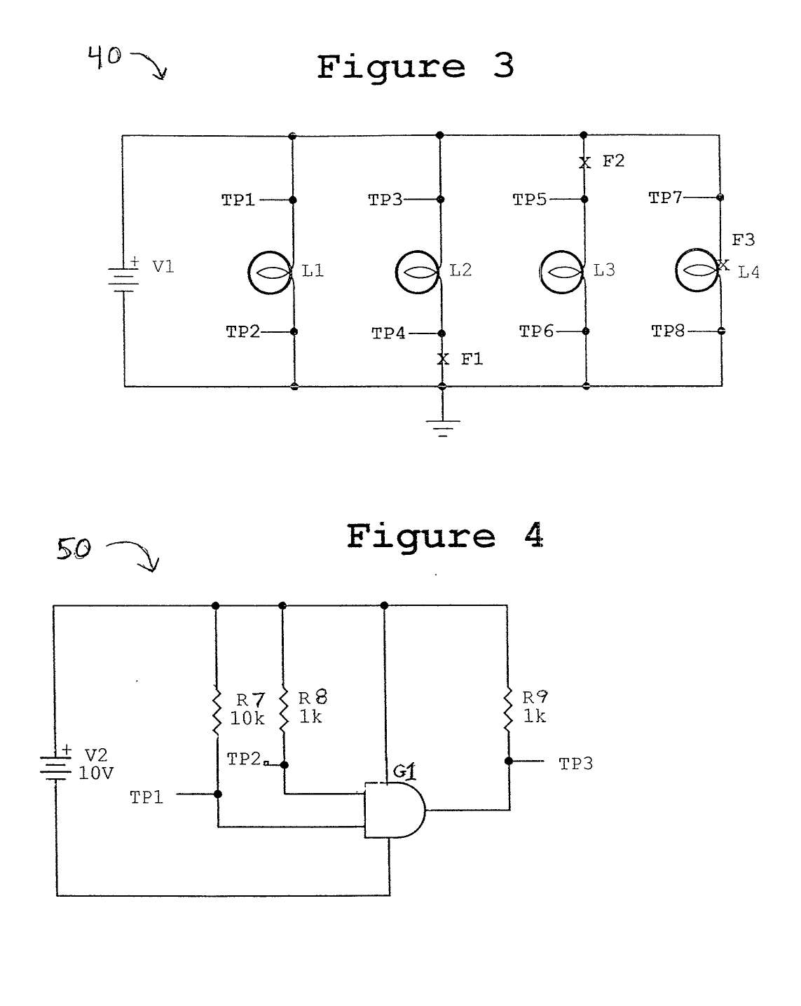

FIG. 3 shows an example circuit 40. Circuit tester 10 may be used to detect faults in example circuit 40. Circuit 40 comprises four lamps L1, L2, L3 and L4 and a battery V1 with positive and negative terminals. The negative terminal is connected to a ground. Lamps L1, L2, L3 and L4 are connected between the positive terminal and ground. Circuit 40 has three faults F1, F2 and F3, which, respectively, prevent lamps L2, L3 and L4 from lighting. Fault F1 is located between L2 and ground, fault F2 is located between L3 and the positive terminal, and fault F3 is located at L4. A user may test circuit 40 by first connecting power clips J1 and J2 of tester 10 to the positive and negative terminals of battery V1. The user can then test circuit 40 by connecting probe J3 to various points of circuit 40. The user connects tip J3 to test points TP1 through TP8 in sequence. If circuit 40 were functioning properly, TP1, TP3, TP5 and TP7 would all produce a red indication from LED D9, and TP2, TP4, TP6 and TP8 would all produce a green indication. The user will see the expected indications of red, green and red when J3 is connected to TP1, TP2 and TP3, respectively. Connecting J3 to TP4 will produce an unexpected red indication. This will indicate to the user that the reason lamp L2 is not illuminated is that there is a break in circuit 40 somewhere between TP4 and ground. The user can determine the source of the problem with lamp L3 by connecting J3 to TP5 and TP6, both of which produce a green indication. This indicates to the user that there is a break in circuit 40 somewhere between T5 and the positive terminal of the battery. When the user connects J3 to TP7 and TP8 red and green indications are produced, respectively. This is the expected result, and from this a user can tell that there are no faults in circuit 40 between the positive terminal and TP7, or between TP8 and ground. This means that the problem with lamp L4 is either a defective connection associated with the lamp socket or that lamp L4 has burned out.

FIG. 4 shows a simple circuit 50 which is used to illustrate some of the advantages of circuit tester 10. Circuit 50 comprises a 10 volt battery V2, three 10 kΩ resistors R7, R8 and R9, and an AND gate G1. A conventional probe connected between any of test points TP1, TP2 or TP3 and ground, would draw TP3 towards ground. In fact, due to the high impedance of circuit 50, most conventional probes that use LEDs would fail to light at all. Furthermore, probing TP1 or TP2 with a conventional probe could shift the input voltage of gate G1 to an unstable level.

All of the above difficulties are avoided if the user connects J1 and J2 across battery V2 and uses tester 10 to probe circuit 50. Connecting J3 to any of TP1, TP2 or TP3 will produce a red indication from LED D9. The load presented to TP1, TP2 or TP3 by tester 10 will be low enough so as to not affect the operation of circuit 50.

As will be apparent to those skilled in the art in the light of the foregoing disclosure, many alterations and modifications are possible in the practice of the invention without departing from the spirit or scope thereof. For example:

resistors R1 and R2 could comprise a potentiometer;

a voltage regulator circuit could be used to provide V_{ref};

indicator 14 could comprise two different LEDs or other lamps, one connected to light when indicator 14 is in the first response state and the other connected to light when indicator 14 is in the second response state;

oscillator 22 may comprise a different oscillator circuit, for example, oscillator 22 may comprise a 555 timer or other integrated circuit timer, a pair of CMOS inverters connected together to form an RC relaxation oscillator, an oscillator comprising discrete circuit elements, or the like;

comparators U1A, U1B and U1C may not all be on one IC chip, and they may each comprise a high-gain differential amplifier, made either with discrete components or an integrated op-amp;

resistor R6 could be replaced with a different device or circuit for limiting the current passing through probe J3.

Accordingly, the scope of the invention is to be construed in accordance with the substance defined by the following claims.

What is claimed is:

1. A circuit tester comprising:
(a) a reference voltage source that provides a reference voltage;
(b) an indicator having first and second response states, said first and second response states producing first and second indications, respectively;
(c) an indicator driver connected to the reference voltage source, the indicator driver having an input, the indicator driver being connected to drive the indicator in the first response state when a voltage at the input is lower than the reference voltage and connected to drive the indicator in a second response state when the voltage at the input is higher than the reference voltage;
(d) an oscillator having an output electrically coupled to the input of the indicator driver; and,
(e) a probe electrically coupled to the input of the indicator driver;
wherein, when the probe is not electrically connected to a circuit under test, the oscillator causes the indicator driver to cycle the indicator between the first and second response states.

2. The circuit tester of claim 1 wherein the indicator comprises a light emitting diode that emits light of a first color and a second color, the first indication comprises displaying the first color and the second indication comprises displaying the second color.

3. The circuit tester of claim 1 wherein the indicator comprises a first light emitting diode and a second light emitting diode, the first indication comprises illuminating the first light emitting diode and the second indication comprises illuminating the second light emitting diode.

4. The circuit tester of claim 1 wherein the oscillator is configured to generate a signal with a frequency high enough so that when the probe is not connected to a circuit under test, the indicator cycles between first and second response states fast enough so that the indicator seems to produce a third indication, the third indication being a mixture of the first and second indications.

5. The circuit tester of claim 2 wherein the oscillator is configured to generate a signal with a frequency high enough that, when the probe is not connected to a circuit under test, the indicator cycles between first and second response states fast enough so that a human eye viewing the indicator will perceive a third color of light being emitted from the light emitting diode, the third color being a blend of the first and second colors.

6. The circuit tester of claim 2 wherein the indicator driver comprises first and second comparators each having an output, a non-inverting input and an inverting input, the light emitting diode is connected between the outputs of the first and second comparators, the reference voltage source is coupled to the non-inverting input of the first comparator and the inverting input of the second comparator, the inverting input of the first comparator is connected to the non-inverting input of the second comparator and the input of the indicator driver is resistively coupled to the inverting input of the first comparator and the non-inverting input of the second comparator.

7. The circuit tester of claim 1 wherein the indicator driver comprises first and second comparators each having an output, a non-inverting input and an inverting input, the indicator is connected between the outputs of the first and second comparators, the reference voltage source is coupled to the non-inverting input of the first comparator and the inverting input of the second comparator, the inverting input of the first comparator is connected to the non-inverting input of the second comparator and the input of the indicator driver is resistively coupled to the inverting input of the first comparator and the non-inverting input of the second comparator.

8. The circuit tester of claim 1 wherein the oscillator comprises a relaxation oscillator.

9. The circuit tester of claim 8 wherein the relaxation oscillator comprises a comparator having first and second inputs and an output, the reference voltage source is connected to the first input, a first resistor is connected between the output and the first input, a capacitor is connected to the second input, and a second resistor is connected between the output and the second input.

10. The circuit tester of claim 1 wherein the reference voltage source comprises a voltage divider.

11. The circuit tester of claim 1 comprising first and second power connectors respectively connected to first and second inputs of a full-wave rectifier having positive and negative outputs, and the reference voltage source comprises a voltage divider connected between the positive and negative outputs.

12. The circuit tester of claim 11 wherein the first and second power connectors are connected to a power source.

13. The circuit tester of claim 12 wherein the power source provides a voltage of between approximately 6 and 24 volts.

14. The circuit tester of claim 13 wherein the indicator driver comprises a current limiter wherein the current limiter causes intensities of each of the first and second response states to be substantially unaffected by variations in the voltage of the power source.

15. The circuit tester of claim 12 wherein the first and second response states of the indicator operate at a full intensity level when the power connectors have made a good connection with the power source, and a lower intensity level when the power connectors have not made a good connection with the power source.

16. The circuit tester of claim 11 wherein the voltage divider comprises two equivalent resistors and the reference voltage source provides a voltage halfway between the positive and negative outputs of the rectifier.

17. The circuit tester of claim 1 comprising a current steering resistor connected in series with the probe.

18. The circuit tester of claim 11 comprising a current steering resistor connected in series with the probe wherein the current steering resistor has a value such that a current passing to the probe does not exceed approximately 1 milliamperes when the power connectors are connected to opposite polarity terminals of a battery having a nominal voltage of 24 volts or less and a voltage the probe is connected to a voltage in the range of 0 to the voltage of the battery.

19. The circuit tester of claim 1 wherein the indicator comprises a audio signal generator, the first indication comprises sound of a first pitch generated by the audio signal generator and the second indication comprises sound of a second pitch generated by the audio signal generator.

20. The circuit tester of claim 1 comprising a power connector connected to a first input of a full-wave rectifier having positive and negative outputs, wherein the probe is connected to a second input of the full-wave rectifier, and the reference voltage source comprises a voltage divider connected between the positive and negative outputs.

21. A circuit tester comprising:
(a) first, second and third connectors;
(b) first, second, third, fourth, fifth and sixth diodes, each diode having an anode and a cathode, the anodes of said first, third and fifth diodes connected to said first, second and third connectors, respectively, and the cathodes of said second, fourth and sixth diodes connected to said first, second and third connectors, respectively; and,
(c) a testing circuit having a positive input, a negative input, and a probe input;
wherein the cathodes of said first, third and fifth diodes are connected to the positive input of said testing circuit, and the anodes of said second, fourth and sixth diodes connected to the negative input of said testing circuit, and one of said connectors is connected to the probe input of said testing circuit.

22. A circuit tester comprising:
a full-wave rectifier circuit having a pair of inputs, a positive output and a negative output;
a probe;
a first and second diode each having an anode and a cathode, the first diode having its anode connected to the probe and its cathode connected to the negative input, the second diode having its anode connected to the positive input and its cathode connected to the probe;
a voltage divider connected between the positive and negative outputs; the voltage divider having a reference voltage output;
first and second comparators each having an inverting input and a non-inverting input, the reference voltage output coupled to the inverting input of the first comparator and the non-inverting input of the second comparator and the probe coupled to the non-inverting output of the first comparator and the inverting input of the second comparator;
an oscillator providing a signal, the signal periodically varying about the reference voltage and coupled to the probe through a series impedance; and,
a two-color light emitting diode coupled between outputs of the first and second comparators.

23. A method of testing a circuit, the method comprising:
(a) producing a reference voltage;
(b) providing a tester circuit comprising an indicator, an oscillator and a probe, the indicator having first and second response states;
(c) connecting the probe to a test point on a circuit under test; and,
(d) producing an indication from the indicator in response to a voltage at the test point,
wherein when the voltage at the test point is lower than the reference voltage the indication comprises the first response state, and when the voltage at the test point is higher than the reference voltage the indication comprises the second response state, and when the test point is floating the indication comprises cycling between the first and second response states at a frequency determined by the oscillator.

24. The method of claim 23 wherein when the voltage at the test point is approximately equal to the reference voltage, the oscillator causes the indication to cycle between the first and second response states.

25. The method of claim 23 wherein the indicator comprises a light emitting diode that emits light of a first color and a second color, and producing the indication comprises emitting one of the first color and the second color.

26. The method of claim 23 wherein the indicator comprises a first light emitting diode and a second light emitting diode, and the indication comprises illuminating one of the first light emitting diode and the second light emitting diode.

27. The method of claim 23 comprising, at a time when the probe is not connected to a circuit under test, causing the oscillator to generate a signal with a frequency high enough that, the indicator cycles between first and second response states fast enough so that an observer of the indication perceives a third response state.

28. The method of claim 25 comprising, at a time when the probe is not connected to a circuit under test, causing the oscillator to generate a signal with a frequency high enough that, the light emitting diode cycles between emitting light of the first and second colors fast enough so that an observer of the indication perceives a third color.

29. The method of claim 23 wherein producing the reference voltage comprises passing an electrical current through resistive elements connected as a voltage divider.

30. The method of claim 23 further comprising providing first and second power connectors respectively connected to first and second inputs of a full-wave rectifier having positive and negative outputs.

31. The method of claim 30 wherein producing the reference voltage comprises connecting resistive elements between the positive and negative outputs of the full-wave rectifier to form a voltage divider.

32. The method of claim 30 further comprising connecting the first and second power connectors to a power source.

33. The method of claim 32 wherein the first and second response states of the indicator operate at a full intensity level when the power connectors have made a good connection with the power source, and a lower intensity level when the power connectors have not made a good connection with the power source.

34. The method of claim 23 further comprising limiting a current passing through the probe to approximately 25 milliamperes.

35. The method of claim 34 wherein limiting the current comprises providing an integrated circuit chip with a short circuit protection feature.

36. The method of claim 23 wherein the indicator comprises a audio signal generator that emits sound of a first pitch and a second pitch, and producing the indication comprises emitting sound of one of the first pitch and the second pitch.

37. The method of claim 23 wherein producing the reference voltage comprises connecting a power connector to a first input of a full-wave rectifier having positive and negative outputs, connecting the probe is connected to a second input of the full-wave rectifier, and connecting resistive elements between the positive and negative outputs of the full-wave rectifier to form a voltage divider.

38. A method of testing a circuit, comprising:
(a) producing a reference voltage;
(b) providing a test circuit comprising a first, a second and a third display element, a display element driver and a probe;
(c) connecting the probe to a test point on a circuit under test; and,
(d) activating one of said display elements,
wherein when a voltage at the test point is lower than the reference voltage the display element driver activates the first display element, and when a voltage at the test point is higher than the reference voltage the display element driver activates the second display element, and when the test point is floating the display element driver activates the third display element.
